(19) United States
(12) Patent Application Publication
(10) Pub. No.: US 2025/0343097 A1
(43) Pub. Date: Nov. 6, 2025

(54) SEMICONDUCTOR PACKAGE

(71) Applicant: Samsung Electronics Co., Ltd., Suwon-si (KR)

(72) Inventors: Yongjin Seol, Suwon-si (KR); Jungeun Koo, Suwon-si (KR); Dongchul Yang, Suwon-si (KR); Sangwoong Lee, Suwon-si (KR); Deokhee Han, Suwon-si (KR); Changui Hong, Suwon-si (KR)

(21) Appl. No.: 18/909,270

(22) Filed: Oct. 8, 2024

(30) Foreign Application Priority Data
May 3, 2024 (KR) 10-2024-0058949

(51) Int. Cl. H01L 23/367; H01L 21/48; H01L 21/56; H01L 23/00; H01L 23/31; H01L 23/373; H01L 23/498; H01L 25/065; H05K 1/18; H10B 80/00

(52) U.S. Cl. CPC H01L 23/3672; H01L 23/3128; H01L 23/3735; H01L 23/49833; H01L 23/49838; H01L 21/4853; H01L 21/4871; H01L 21/56; H01L 23/562; H01L 24/16; H01L 24/32; H01L 24/48; H01L 24/73; H01L 25/0657; H01L 2224/08225; H01L 2224/16225; H01L 2224/32145; H01L 2224/32225; H01L 2224/48147; H01L 2224/48227; H01L 2224/73204; H01L 2224/73265; H01L 2225/06506; H01L 2225/0651; H01L 2225/06548; H01L 2225/06562; H01L 2924/1431; H05K 1/181; H10B 80/00

(57) ABSTRACT

A semiconductor package includes a lower redistribution structure, a lower chip structure, an encapsulant, an upper redistribution structure, a plurality of posts, an upper chip structure, a heat dissipation member that is on a first side of the upper chip structure and overlaps at least a portion of the lower chip structure in a first direction, and external connection bumps. In plan view, the heat dissipation member includes a first surface, a second surface a third surface and a fourth surface. The second surface of the heat dissipation member faces the first side of the upper chip structure. At least one of the first surface, the third surface, and the fourth surface of the heat dissipation member overlaps an edge of the lower redistribution structure, an edge of the encapsulant, and an edge of the upper redistribution structure in the first direction.

### CROSS-REFERENCE TO RELATED APPLICATION(S)

This application claims benefit of priority to Korean Patent Application No. 10-2024-0058949 filed on May 3, 2024 in the Korean Intellectual Property Office, the disclosure of which is incorporated herein by reference in its entirety.

### BACKGROUND

The present disclosure relates to a semiconductor package.

As decreases in weight and increases in performance of electronic devices are implemented, there is a demand for development of a semiconductor chip having a small size and increased performance. In order to improve reliability of the semiconductor chip having increased performance, the importance of heat dissipation characteristics of a semiconductor package is increasing.

### SUMMARY

An aspect of the present disclosure is to provide a semiconductor package having improved reliability.

According to an aspect of the present disclosure, a semiconductor package includes a lower redistribution structure that includes a lower redistribution layer, a lower chip structure that is on an upper surface of the lower redistribution structure and is electrically connected to the lower redistribution layer, an encapsulant on the lower chip structure, an upper redistribution structure that is on the encapsulant and includes an upper redistribution layer, a plurality of posts that extend into the encapsulant and electrically connect the lower redistribution layer and the upper redistribution layer, an upper chip structure that is on the upper redistribution structure and is electrically connected to the upper redistribution layer, a heat dissipation member that is on a first side of the upper chip structure and overlaps at least a portion of the lower chip structure in a first direction that is perpendicular to a lower surface of the lower redistribution structure that is opposite to the lower surface of the lower redistribution structure, and external connection bumps that are on the lower surface of the lower redistribution structure and are electrically connected to the lower redistribution layer. In plan view, the heat dissipation member includes a first surface, a second surface a third surface and a fourth surface. The second surface of the heat dissipation member faces the first side of the upper chip structure. At least one of the first surface, the third surface, and the fourth surface of the heat dissipation member overlaps an edge of the lower redistribution structure, an edge of the encapsulant, and an edge of the upper redistribution structure in the first direction.

According to an aspect of the present disclosure, a semiconductor package includes a unit package structure that includes a lower chip structure, where the unit package structure includes a first side surface and a second side surface that are opposite to each other, and where the unit package structure includes a third side surface and a fourth side surface that are opposite to each other, a heat dissipation member that is on the unit package structure and adjacent to the first side surface, an upper chip structure that is on the unit package structure and adjacent to the second side surface, a heat transfer material layer between the upper chip structure and the unit package structure, and external connection bumps that are on the unit package structure and are electrically connected to the lower chip structure and the upper chip structure. The heat dissipation member includes a first surface adjacent to the first side surface of the unit package structure, a second surface adjacent to the upper chip structure, a third surface adjacent to the third side surface, and a fourth surface adjacent to the fourth side surface. The heat transfer material layer includes a first edge adjacent to the first surface, a second edge adjacent to the second surface, a third edge adjacent to the third surface, and a fourth edge adjacent to the fourth surface. The first surface of the heat dissipation member is aligned with the first side surface of the unit package structure in a first direction that is perpendicular to a lower surface of the unit package structure, the third surface of the heat dissipation member is aligned with the third side surface of the unit package structure in the first direction, and/or the fourth surface of the heat dissipation member is aligned with the fourth side surface of the unit package structure in the first direction. The first edge of the heat transfer material layer is spaced apart from the first side surface of the unit package structure in a second direction that is parallel to the lower surface of the unit package structure, the third edge of the heat transfer material layer is spaced apart from the third side surface of the unit package structure in the second direction, and/or the fourth edge of the heat transfer material layer is spaced apart from the fourth side surface of the unit package structure in the second direction.

According to an aspect of the present disclosure, a semiconductor package includes a unit package structure that includes a lower redistribution structure, a lower chip structure on the lower redistribution structure, an upper redistribution structure on the lower chip structure, and a plurality of posts electrically connecting the lower redistribution structure and the upper redistribution structure, and a heat dissipation member and an upper chip structure that are on the unit package structure. In plan view, the heat dissipation member extends to an edge of the unit package structure in at least one of a first direction, a third direction perpendicular to the first direction, and a fourth direction opposite to the third direction. The heat dissipation member is adjacent to the upper chip structure in a second direction that is opposite to the first direction.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a plan view of a semiconductor package according to an example embodiment, and FIG. 1B is a cross-sectional view of FIG. 1A, taken along line I-I′.

FIGS. 2A and 2B are views illustrating semiconductor packages of example embodiments.

FIGS. 3A and 3B are cross-sectional views illustrating an example embodiment of a lower chip structure applicable to the semiconductor package of FIG. 1A.

FIG. 3C is a cross-sectional view illustrating an example embodiment of an upper chip structure applicable to the semiconductor package of FIG. 1A.

FIG. 4A is a plan view of a semiconductor package according to an example embodiment, and FIG. 4B is a cross-sectional view of FIG. 4A, taken along line II-II′.

FIG. 5A is a plan view of a semiconductor package according to an example embodiment, and FIG. 5B is a cross-sectional view of FIG. 5A, taken along line III-III′.

FIG. 6A is a plan view of a semiconductor package according to an example embodiment, and FIG. 6B is a cross-sectional view of FIG. 6A, taken along line IV-IV′.

FIGS. 7A, 7B, 7C, 7D, 7E, 7F, 7G, 7H, and 7I are cross-sectional views illustrating a process of manufacturing a semiconductor package according to an example embodiment.

FIGS. 8A, 8B, and 8C are views illustrating heat dissipation blocks of example embodiments.

FIGS. 9A, 9B, and 9C are plan views illustrating a portion of a process of manufacturing a semiconductor package according to an example embodiment.

FIGS. 10A to 10C are plan views illustrating heat dissipation blocks of example embodiments.

### DETAILED DESCRIPTION

Hereinafter, embodiments of the present disclosure will be described with reference to the accompanying drawings. Hereinafter, it can be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. Further, spatially relative terms may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly. Additionally, ordinal numbers such as “first,” “second,” “third,” or the like may be used as labels for specific elements, steps, operations, directions, or the like to distinguish various elements, steps, operations, directions, or the like from each other. Terms that may not be described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim).

Since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction

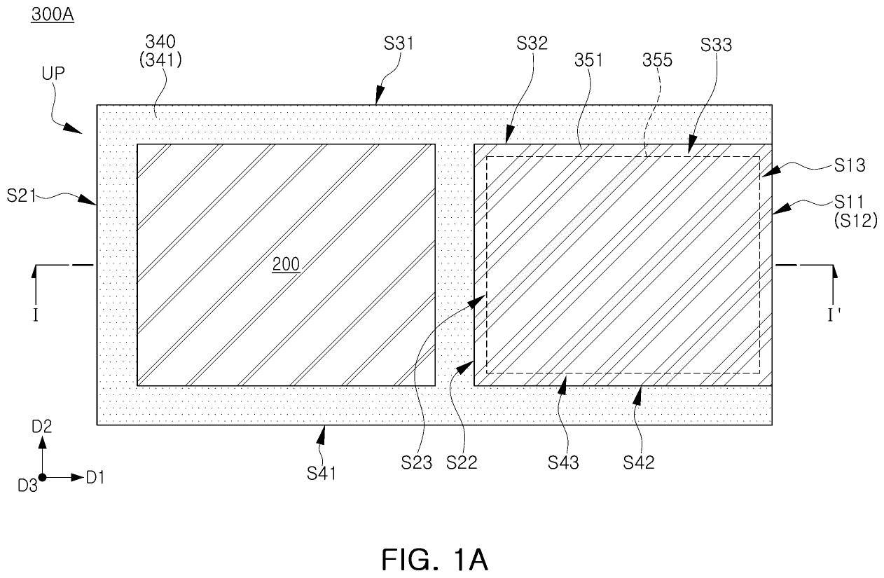

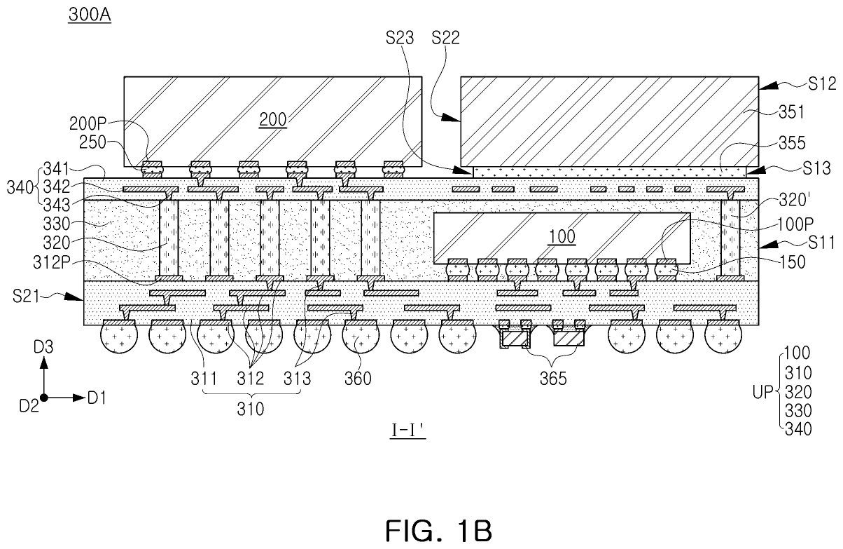

FIG. 1A is a plan view of a semiconductor package 300A according to an example embodiment, and FIG. 1B is a cross-sectional view of FIG. 1A, taken along line I-I′.

Referring to FIGS. 1A and 1B, a semiconductor package 300A may include a unit package structure UP, an upper chip structure 200, and a heat dissipation member 351. The upper chip structure 200 and the heat dissipation member 351 may be disposed adjacent to each other on the unit package structure UP. The unit package structure UP may include a lower chip structure 100, a lower redistribution structure 310, a plurality of posts 320, an encapsulant 330, and an upper redistribution structure 340.

The lower chip structure 100 may be disposed on the lower redistribution structure 310, and may include first connection terminals 100P electrically connected to a lower redistribution layer 312. The first connection terminals 100P may be connected to the lower redistribution layer 312 through lower connection bumps 150 disposed between the lower chip structure 100 and the lower redistribution structure 310.

The upper chip structure 200 may be disposed on the upper redistribution structure 340. The upper chip structure 200 may be electrically connected to the lower redistribution layer 312 through an upper redistribution layer 342 and the plurality of posts 320. The upper chip structure 200 may include second connection terminals 200P electrically connected to the upper redistribution layer 342. The second connection terminals 200P may be connected to the plurality of posts 320 through upper connection bumps 250 disposed between the upper chip structure 200 and the upper redistribution structure 340. An underfill material layer (not illustrated) may be formed below the upper chip structure 200 to surround the upper connection bumps 250.

The upper chip structure 200 may be arranged to vertically overlap at least a portion of the plurality of posts 320. Additionally, the upper chip structure 200 may be arranged to be staggered (or spaced apart) from the lower chip structure 100 in a horizontal direction, to expose at least a portion of the lower chip structure 100 in a vertical direction (D3 direction, which is perpendicular to a lower surface of the lower redistribution structure 310). The upper chip structure 200 may be disposed on one side of the heat dissipation member 351 disposed on the lower chip structure 100.

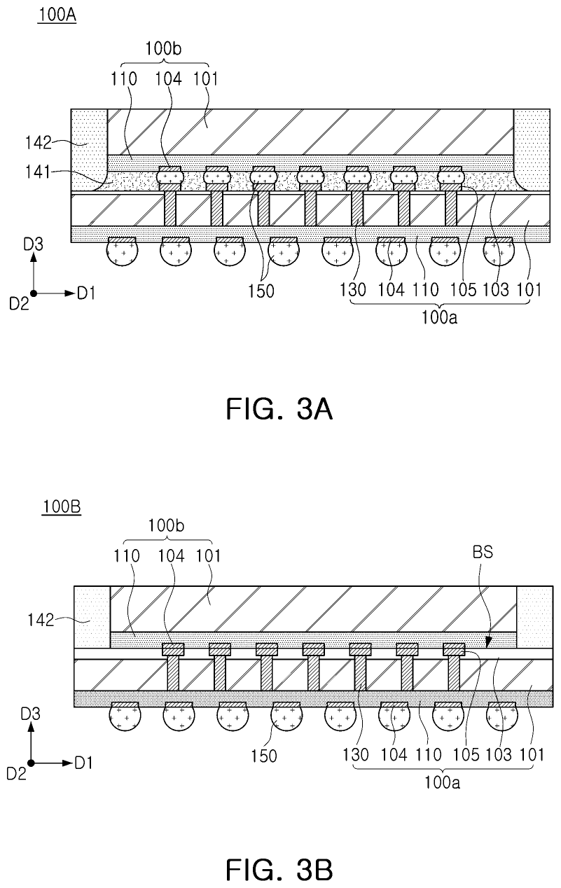

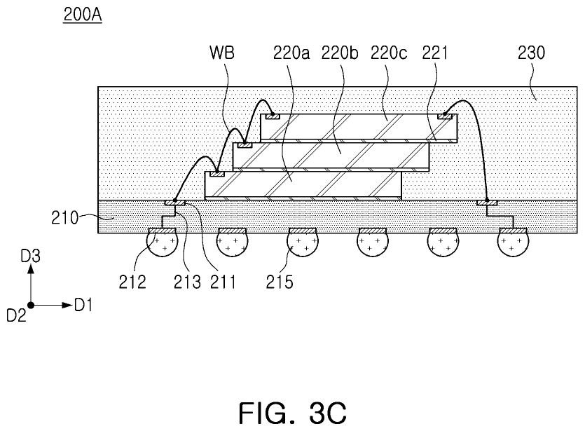

The lower chip structure 100 and the upper chip structure 200 may include a semiconductor wafer and a semiconductor wafer integrated circuit (IC), formed of a semiconductor element such as silicon or germanium, or a compound semiconductor such as silicon carbide (SiC), gallium arsenide (GaAs), indium arsenide (InAs), or indium phosphide (InP). The lower chip structure 100 and the upper chip structure 200 may be bare semiconductor chips without a separate bump or wiring layer, but the present disclosure is not limited thereto, and may be packaged type semiconductor chips. An integrated circuit may be a logic circuit (or ‘logic chip’) such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory circuit (or ‘memory chip’) including a volatile memory such as a dynamic RAM (DRAM), a static RAM (SRAM), or the like, and a non-volatile memory such as a phase change RAM (PRAM), a magnetic RAM (MRAM), a resistive RAM (RRAM), a flash memory, or the like. The lower chip structure 100 and the upper chip structure 200 may include different types of semiconductor chips. For example, the lower chip structure 100 may include at least one logic chip, and the upper chip structure 200 may include at least one memory chip. Depending on an embodiment, the lower chip structure 100 and the upper chip structure 200 may each be a package structure including a plurality of semiconductor chips, which will be described later with reference to FIGS. 3A to 3C.

The lower redistribution structure 310 may be a support substrate on which the lower chip structure 100 is mounted, and may include a lower insulating layer 311, lower redistribution layers 312, and lower redistribution vias 313.

The lower insulating layer 311 may include an insulating resin. The insulating resin may be a thermosetting resin such as an epoxy resin, a thermoplastic resin such as polyimide, or a resin in which an inorganic filler or the like is impregnated into the resins, such as a prepreg, an Ajinomoto build-up film (ABF), an FR-4, or bismaleimide-triazine (BT). For example, the lower insulating layer 311 may include a photosensitive resin such as a photoimageable dielectric (PID). The lower insulating layer 311 may include a plurality of insulating layers (not illustrated) stacked in the vertical direction (Z-axis direction). Depending on a process, a boundary between the plurality of insulating layers (not illustrated) may be unclear or indistinct.

The lower redistribution layer 312 may be disposed on or in the lower insulating layer 311, and may redistribute the first connection terminal 100P of the lower chip structure 100. The lower redistribution layer 312 may include, for example, metal including copper (Cu), aluminum (Al), silver (Ag), tin (Sn), gold (Au), nickel (Ni), lead (Pb), titanium (Ti), or alloys thereof. The lower redistribution layer 312 may perform various functions depending on a design. For example, the lower redistribution layer 312 may include a ground pattern, a power pattern, and a signal pattern. In this case, the signal pattern may provide a transmission path for various signals, for example, a data signal or the like, excluding the ground pattern, the power pattern, or the like. The lower redistribution layer 312 may include more or fewer redistribution layers, as compared to those illustrated in the drawings. The lower redistribution layer 312 may include redistribution pads 312P disposed on an upper surface of the lower redistribution structure 310. The redistribution pads 312P may be electrically connected to the plurality of posts 320 and the first connection terminals 100P of the lower chip structure 100.

The lower redistribution via 313 may extend vertically in the lower insulating layer 311, and may be electrically connected to the lower redistribution layer 312. For example, the lower redistribution via 313 may interconnect lower redistribution layers 312 on different levels. The lower redistribution via 313 may include a signal via, a ground via, and a power via. The lower redistribution via 313 may include, for example, a metal material including copper (Cu), aluminum (Al), silver (Ag), tin (Sn), gold (Au), nickel (Ni), lead (Pb), titanium (Ti), or alloys thereof. The lower redistribution via 313 may be a filled via in which an internal space of a via hole is filled with or includes a metal material, or a conformal via in which a metal material extends along an inner wall of a via hole.

External connection bumps 360 may be disposed below the lower redistribution structure 310. The external connection bumps 360 may be electrically connected to the lower redistribution layer 312. The semiconductor package 300A may be connected to an external device such as a module substrate, a system board, or the like through the external connection bumps 360. The external connection bumps 360 may have a combined shape of a pillar (or underbump metal) and a ball. The pillar may include copper (Cu) or an alloy of copper (Cu), and the ball may include a low melting point metal, for example, tin (Sn) or an alloy including tin (Sn) (Sn-Ag-Cu). Depending on an embodiment, the external connection bumps 360 may include only the pillar or the ball. Depending on an embodiment, a resist layer (not illustrated) may be formed on a lower surface of the lower redistribution structure 310, to protect the external connection bumps 360 from physical and chemical damage.

Additionally, at least one passive element 365 may be disposed below the lower redistribution structure 310. The passive element 365 may include, for example, a capacitor, an inductor, a bead, or the like. The passive element 365 may be flip-chip bonded to the lower surface of the lower redistribution structure 310. The passive element 365 may be electrically connected to the lower redistribution layer 312 through a solder bump or the like. An underfill resin may be filled between the passive element 365 and the lower redistribution structure 310. The plurality of posts 320 may pass through or extend into the encapsulant 330 to

electrically connect the lower redistribution layer 312 and the upper redistribution layer 342. The plurality of posts 320 may be formed of copper (Cu), nickel (Ni), titanium (Ti), lead (Pb), aluminum (Al), silver (Ag), gold (Au), platinum (Pt), or alloys thereof. The plurality of posts 320 may extend in the encapsulant 330 in the vertical direction (D3 direction). The plurality of posts 320 may have a cylindrical shape, but the present disclosure is not limited thereto.

The plurality of posts 320 may be asymmetrically arranged around the lower chip structure 100. Some of the plurality of posts 320 may be disposed in a region overlapping the upper chip structure 200. A post 320′, which is at least a portion of the plurality of posts 320, may be disposed in a region overlapping the heat dissipation member 351. For example, the number of the plurality of posts 320 overlapping the upper chip structure 200 in the vertical direction D3 may be greater than the number of posts 320′ overlapping the heat dissipation member 351 in the vertical direction D3.

The encapsulant 330 may cover or surround at least a portion of the lower chip structure 100 and at least a portion of the plurality of posts 320. The encapsulant 330 may cover or overlap a side surface of the lower chip structure 100 and a side surface of each of the plurality of posts 320. The encapsulant 330 may expose an upper surface of each of the plurality of posts 320. Depending on an embodiment, the encapsulant 330 may expose an upper surface of the lower chip structure 100. The upper surface of the encapsulant 330 may be substantially coplanar with the upper surface of the lower chip structure 100 and the upper surface of the plurality of posts 320. The encapsulant 330 may include, for example, a thermosetting resin such as an epoxy resin, a thermoplastic resin such as polyimide, or a prepreg, an ABF, an FR-4, BT, or an epoxy molding compound (EMC). For example, the encapsulant 330 may include the EMC.

The upper redistribution structure 340 may be disposed on the encapsulant 330, and may include an upper insulating layer 341, upper redistribution layers 342, and an upper redistribution via 343. The upper redistribution structure 340 may electrically connect the post 320′ at positions that do not overlap the upper chip structure 200.

The upper insulating layer 341 may include a thermosetting resin such as an epoxy resin, a thermoplastic resin such as polyimide, or a resin in which an inorganic filler or the like is impregnated into the resins, such as a prepreg, an Ajinomot build-up film (ABF), an FR-4, or bismaleimide-triazine (BT). For example, the upper insulating layer 341 may include a photosensitive resin such as PID. The upper insulating layer 341 may include a plurality of insulating layers (not illustrated) stacked in the vertical direction (D3 direction). Depending on a process, a boundary between the plurality of insulating layers (not illustrated) may be unclear or indistinct.

The upper redistribution layer 342 may be disposed on or in the upper insulating layer 341, and may redistribute the second connection terminal 200P of the upper chip structure 200. The upper redistribution layer 342 may include, for example, metal including copper (Cu), aluminum (Al), silver (Ag), tin (Sn), gold (Au), nickel (Ni), lead (Pb), titanium (Ti), or alloys thereof. The upper redistribution layer 342 may perform various functions depending on a design. The upper redistribution layer 342 may include more or fewer redistribution layers, as compared to those illustrated in the drawings.

The upper redistribution via 343 may extend vertically in the upper insulating layer 341, and may be electrically connected to the upper redistribution layer 342. For example, the upper redistribution via 343 may interconnect upper redistribution layers 342 on different levels. The upper redistribution via 343 may include, for example, a metal material including copper (Cu), aluminum (Al), silver (Ag), tin (Sn), gold (Au), nickel (Ni), lead (Pb), titanium (Ti), or alloys thereof. The upper redistribution via 343 may be a filled via in which an internal space of a via hole is filled with or includes a metal material, or a conformal via in which a metal material extends along an inner wall of a via hole.

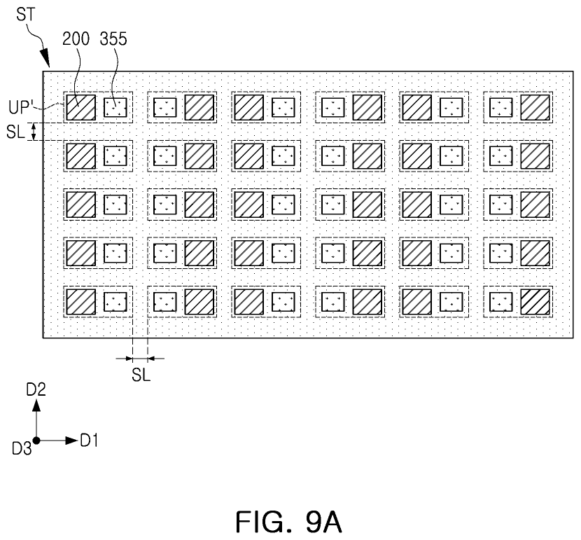

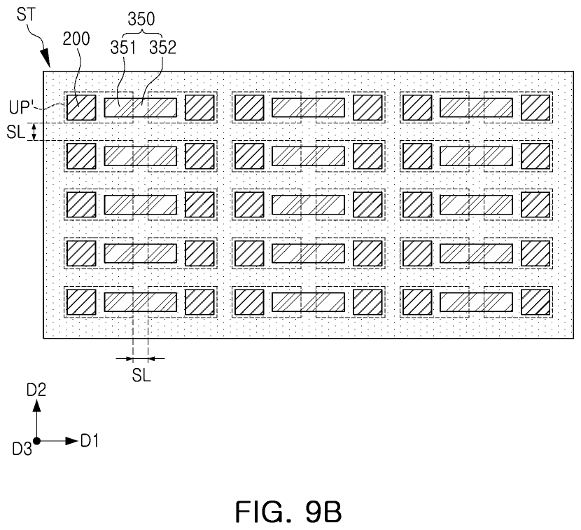

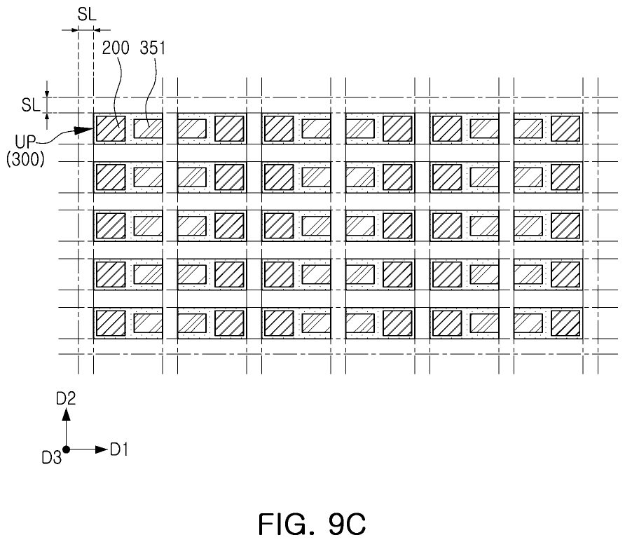

The heat dissipation member 351 may be disposed on one side of the upper redistribution structure 340 to vertically overlap at least a portion of the lower chip structure 100 (D3 direction). The heat dissipation member 351 may control warpage of the semiconductor package 300A, and may dissipate heat generated from the lower chip structure 100 externally. The heat dissipation member 351 may include a material having excellent thermal conductivity, for example, aluminum (Al), gold (Au), silver (Ag), copper (Cu), iron (Fe), graphite, graphene, or the like. The heat dissipation member 351 may be a remaining portion of a heat dissipation block that covers or overlaps multiple unit regions in a substrate strip. According to an example embodiment, warpage of the substrate strip may be controlled, and process risks may be minimized by the heat dissipation block. This will be described in more detail with reference to FIGS. 9A to 9C.

The heat dissipation member 351 may share at least one cut surface with the unit package structure UP. A perimeter of the heat dissipation member 351 may include a portion facing the upper chip structure 200 and a portion facing an end (or edge) of the unit package structure UP. For example, the end (or edge) of the unit package structure UP may include a first side surface S11 facing a first direction D1, a second side surface S21 facing a second direction (e.g., a direction opposite to D1), and opposite to the first direction D1, a third side surface S31 facing a third direction D2 and perpendicular to the first direction D1, and a fourth side surface S41 facing a fourth direction (e.g., a direction opposite to D2) and opposite to the third direction D2. The first side surface S11, the second side surface S21, the third side surface S31, and the fourth side surface S41 of the unit package structure UP may be defined by the lower redistribution structure 310, the encapsulant 330, and the upper redistribution structure 340. For example, the heat dissipation member 351 may be disposed adjacent to the first side surface S11 of the unit package structure UP, and the upper chip structure 200 may be disposed adjacent to the second surface S21 of the unit package structure UP.

In plan view, the heat dissipation member 351 may extend to the end (or edge) (e.g., the first side surface S11, the third side surface S31, and the fourth side surface S41) of the unit package structure UP in at least one direction, among the first direction D1, the third direction D2, and the fourth direction (e.g., the direction opposite to D2), and may be adjacent to the upper chip structure in the second direction (e.g., the direction opposite to D1).

In plan view, the heat dissipation member 351 may include a first surface S12, a second surface S22, a third surface S32, and a fourth surface S42. The second surface S22 of the heat dissipation member 351 may face one side of the upper chip structure 200. At least one surface among the first, third, and fourth surfaces S12, S32, and S42 of the heat dissipation member 351 may match or overlap the end (or edge) of the unit package structure UP (the end (or edge) of the lower redistribution structure 310, the end (or edge) of the encapsulant 330, and the end (or edge) of the upper redistribution structure 340) (e.g., the first side surface S11, the third side surface S31, and the fourth side surface S41).

The at least one surface among the first surface S12, the third surface S32, and the fourth surface S42 of the heat dissipation member 351 may be aligned with the end (or edge) (e.g., the first side surface S11, the third side surface S31, or the fourth side surface S41) of the unit package structure UP, respectively, in the vertical direction (D3).

The at least one surface among the first surface S12, the third surface S32, and the fourth surface S42 of the heat dissipation member 351 may be coplanar with one side surface respectively, among the first side surface S11, the third side surface S31, and the fourth side surface S41.

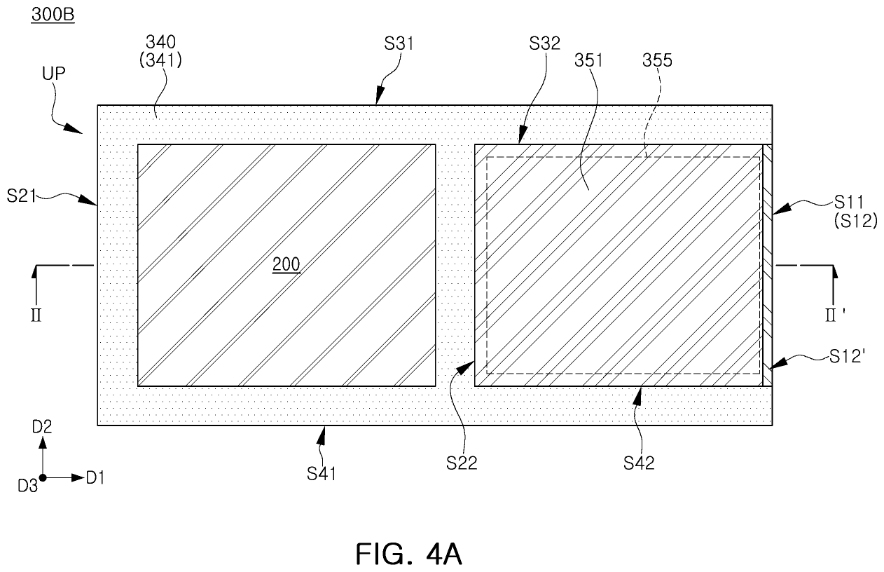

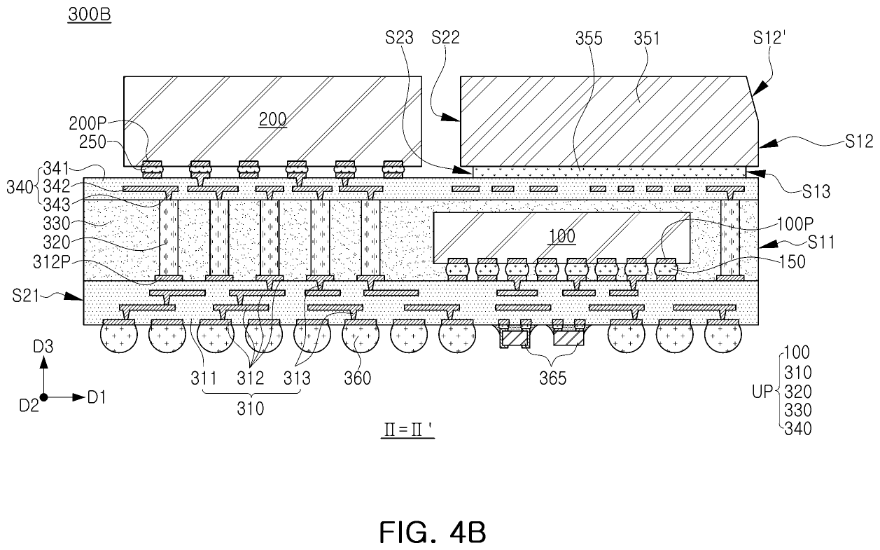

Depending on an embodiment, the heat dissipation member 351 may further include a processing portion formed on at least one surface among the first surface S12, the third surface S32, and the fourth surface S42. The processing portion may be formed to facilitate a cutting process of a heat dissipation block, and may remain in the form of, for example, an inclined surface, a trench, a coating portion, or the like after the cutting process (see FIGS. 4A to 6B, and 8A to 8C).

The heat dissipation member 351 may be attached to the unit package structure UP by a heat transfer material layer 355. The heat transfer material layer 355 may be disposed between the unit package structure UP and the heat dissipation member 351. For example, the heat transfer material layer 355 may include a thermal interface material (TIM) such as a thermally conductive adhesive tape, a thermally conductive grease, a thermally conductive adhesive, or the like. The heat transfer material layer 355 may be spaced apart from a cut surface of the heat dissipation member 351 and a cut surface of the unit package structure UP, to thereby more easily perform the cutting process.

The heat transfer material layer 355 may be located in a planar area (e.g., a flat area) of the heat dissipation member 351. For example, the heat transfer material layer 355 may include a first end S13, a second end S23, a third end S33, and a fourth end S43, respectively corresponding to the first surface S12, the second surface S22, the third surface S32, and the fourth surface S42 of the heat dissipation member 351. In FIGS. 1A and 1B, the first end S13, the second end S23, the third end S33, and the fourth end S43 of the heat transfer material layer 355 are each illustrated as a flat surface (illustrated by a straight line), but the present disclosure is not limited thereto. Depending on an embodiment, the ends or edges (S13, S23, S33, and S43) of the heat transfer material layer 355 may have a curved surface or a curved shape, and the ends or edges (S13, S23, S33, and S43) corresponding to the first surface S12, the second surface S22, the third surface S32, and the fourth surface S42 of the heat dissipation member 351 may not be clearly distinguished.

At least a portion of each of the first end S13, the second end S23, the third end S33, and the fourth end S43 of the heat transfer material layer 355 may be spaced apart from the first surface S12, the second surface S22, the third surface S32, and the fourth surface S42 of the heat dissipation member 351, respectively, in the horizontal direction. In addition, at least a portion of each of the first end S13, the second end S23, the third end S33, and the fourth end S43 of the heat transfer material layer 355 may be spaced apart from the first side surface S11, the second side surface S21, the third side surface S31, and the fourth side surface S41 of the unit package structure UP, respectively, in the horizontal direction.

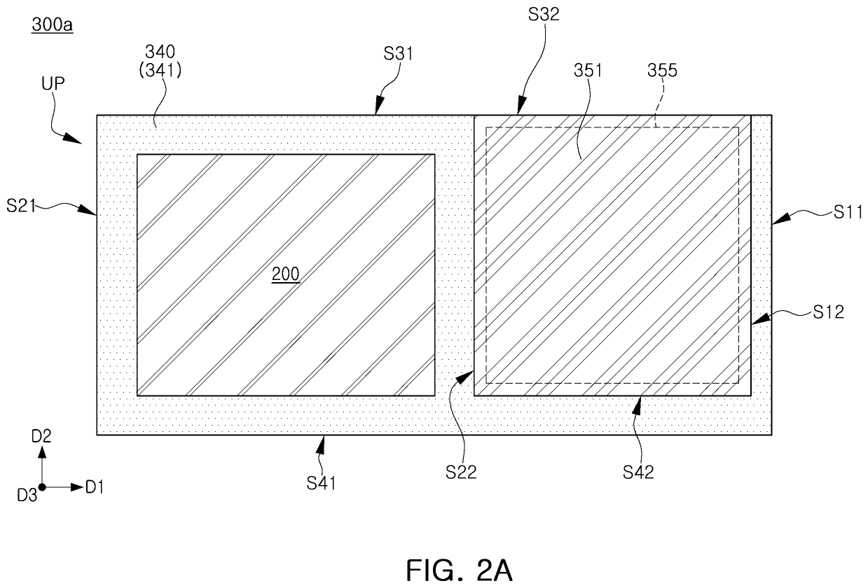

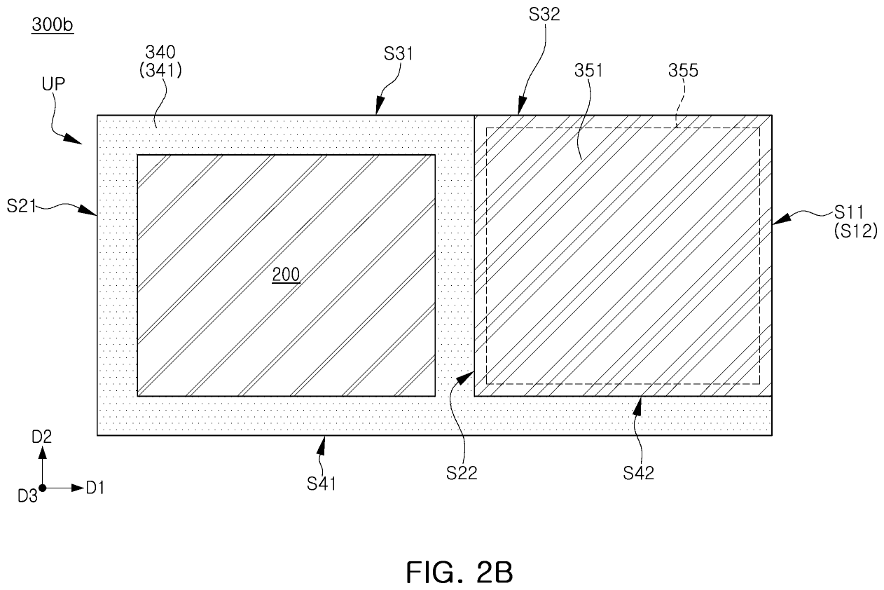

FIGS. 2A and 2B are views illustrating semiconductor packages 300a and 300b of example modified embodiments. FIGS. 2A and 2B illustrate example modified embodiments to the heat dissipation member 351 of FIG. 1A.

Referring to FIG. 2A, in a semiconductor package 300a of an example embodiment, a heat dissipation member 351 may extend to an end (or edge) of a unit package structure UP, in a direction (e.g., D2) perpendicular to an arrangement direction (e.g., D1) of an upper chip structure 200 and the heat dissipation member 351. A first surface S12 of the heat dissipation member 351 may be spaced apart from a first side surface S11 of the unit package structure UP. At least one of a third surface S32 or a fourth surface S42 of the heat dissipation member 351 may be aligned with a third side surface S31 and a fourth side surface S41 of the unit package structure UP, respectively, in a vertical direction (D3). On a plane, at least one of the third and fourth surfaces S32 and S42 of the heat dissipation member 351 may match or overlap the third side surface S31 and the fourth side surface S41 of the unit package structure UP, respectively.

Referring to FIG. 2B, in a semiconductor package 300b of an example embodiment, a heat dissipation member 351 may extend to an end (or edge) of a unit package structure UP in at least two directions (e.g., D1 and D2). On a plane, two surfaces among a first surface S12, a third surface S32, and a fourth surface S42 of the heat dissipation member 351 may match or overlap ends of the unit package structures UP, respectively. On a plane, a remaining one of the first surface S12, the third surface S32, or the fourth surface S42 of the heat dissipation member 351 may be spaced apart from an end (or edge) of the unit package structure UP, respectively. Depending on an embodiment, the first surface S12, the third surface S32, and the fourth surface S42 of the heat dissipation member 351 may all match ends of the unit package structure UP, respectively.

FIGS. 3A and 3B are cross-sectional views illustrating an example embodiment of a lower chip structure 100 applicable to the semiconductor package 300A of FIG. 1A, and FIG. 3C is a cross-sectional view illustrating an example embodiment of an upper chip structure 200 applicable to the semiconductor package 300A of FIG. 1A.

Referring to FIG. 3A, a lower chip structure 100A of the example embodiment may include a plurality of semiconductor chips 100a and 100b, stacked in a vertical direction (D3 direction). At least some of the plurality of semiconductor chips 100a and 100b (e.g., ‘100a’) may include through-vias 130 electrically connecting the plurality of semiconductor chips 100a and 100b to each other. The plurality of semiconductor chips 100a and 100b may be chips constituting a multi-chip module (MCM). The plurality of semiconductor chips 100a and 100b may include a central processor (CPU), a graphics processor (GPU), a field programmable gate array (FPGA), a digital signal processor (DSP), a cryptographic processor, a microprocessor, a microcontroller, an analog-digital converter, an application-specific integrated circuit (ASIC), a volatile memory, a non-volatile memory, an input/output (I/O) circuit, an analog circuit, a serial-parallel conversion circuit, or the like.

The lower chip structure 100A may include a first semiconductor chip 100a and a second semiconductor chip 100b, the first semiconductor chip 100a may include a processor circuit, and the second semiconductor chip 100b may include at least one of an input/output circuit, an analog circuit, a memory circuit, or a serial-parallel conversion circuit for a processor circuit. The number of the plurality of semiconductor chips 100a and 100b may be greater than the number illustrated in the drawings. Depending on an embodiment, the lower chip structure 100A may further include a molding member 142 covering or overlapping at least a portion of the first semiconductor chip 100a and at least a portion of the second semiconductor chip 100b. Depending on an embodiment, an underfill portion 141 may be formed between the first semiconductor chip 100a and the second semiconductor chip 100b.

The first semiconductor chip 100a and the second semiconductor chip 100b may include a substrate 101, an upper protective layer 103, an upper pad 105, a circuit layer 110, a lower pad 104, and/or a through-via 130. The substrate 101 may include, for example, a semiconductor element such as silicon or germanium, or may include a compound semiconductor such as silicon carbide (SiC), gallium arsenide (GaAs), indium arsenide (InAs), or indium phosphide (InP). The substrate 101 may have a silicon-on-insulator (SOI) structure. The substrate 101 may have a conductive region, for example, a well doped with an impurity, or an active surface doped with an impurity and a non-active surface opposite thereto. The substrate 101 may include various device isolation structures, such as a shallow trench isolation (STI) structure.

The upper protective layer 103 may be formed on the non-active surface of the substrate 101, and may protect the substrate 101. The upper protective layer 103 may be formed of an insulating layer such as a silicon oxide film, a silicon nitride film, or a silicon oxynitride film, but a material of the upper protective layer 103 is not limited to the above materials. For example, the upper protective layer 103 may be formed of a polymer such as polyimide (PI). Although not illustrated in the drawings, a lower protective layer may be further formed on a lower surface of the circuit layer 110.

The upper pad 105 may be disposed on the upper protective layer 103. The upper pad 105 may include, for example, at least one of aluminum (Al), copper (Cu), nickel (Ni), tungsten (W), platinum (Pt), or gold (Au). The lower pad 104 may be disposed below the circuit layer 110, and may include a material, similar to a material of the upper pad 105. However, the materials of the upper pad 105 and lower pad 104 are not limited to the above materials.

The circuit layer 110 may be disposed on the active surface of the substrate 101, and may include various types of devices. For example, the circuit layer 110 may include a field effect transistor (FET) such as a planar FET, a FinFET, or the like, a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), and a resistive random access memory (RRAM), or the like, a logic element such as AND, OR, NOT, or the like, or various active and/or passive devices such as a system large scale integration (LSI), a CMOS imaging sensor (CIS), a micro-electro-mechanical system (MEMS). The circuit layer 110 may include a wiring structure electrically connected to the above-described elements, and an interlayer insulating layer surrounding the wiring structure. The interlayer insulating layer may include silicon oxide or silicon nitride. The interconnect structure may include multilayer wirings and/or vertical contacts. The wiring structure may connect elements of the circuit layer 110 to each other, may connect the elements to conductive regions of the substrate 101, or may connect the elements to the through-via 130.

The through-via 130 may pass through or extend into the substrate 101 in the vertical direction (D3 direction), and may provide an electrical path connecting the upper pad 105 and the lower pads 104. The through-via 130 may include a conductive plug and a barrier film surrounding the same. The conductive plug may include metal, such as tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed as an oxide film, a nitride film, a carbide film, a polymer, or a combination thereof. The conductive barrier film may be disposed between the insulating barrier film and the conductive plug. The conductive barrier film may include a metal compound such as, for example, tungsten nitride (WN), titanium nitride (TiN), or tantalum nitride (TaN). The barrier film may be formed by a PVD process or a CVD process.

Connection bumps 150 may be disposed below the first semiconductor chip 100a, and between the first semiconductor chip 100a and the second semiconductor chip 100b. The connection bumps 150 may have a combined shape of a pillar (or underbump metal) and a ball. The pillar may include copper (Cu) or an alloy of copper (Cu), and the ball may include a low melting point metal, for example, tin (Sn) or an alloy including tin (Sn) (Sn-Ag-Cu). Depending on an embodiment, the connection bumps 150 may have a shape consisting of only the pillars or the balls.

Referring to FIG. 3B, a lower chip structure 100B of the example embodiment may include a plurality of semiconductor chips 100a and 100b, directly bonded and coupled without a separate connecting members (e.g., solder bump, copper post, or the like). The lower chip structure 100B may include a bonding surface BS in which an upper surface of a first semiconductor chip 100a and a lower surface of a second semiconductor chip 100b are bonded. The bonding surface BS may be formed by metal bonding and dielectric bonding. For example, an upper protective layer 103 of the first semiconductor chip 100a and a circuit layer 110 of the second semiconductor chip 100b, forming the bonding surface BS, may include materials that may be bonded to each other, for example, at least one of silicon oxide (SiO), silicon nitride (SiN), or silicon carbonitride (SiCN).

Referring to FIG. 3C, an upper chip structure 200A of the example embodiment may include a substrate 210, a plurality of semiconductor chips 200a, 200b, and 200c, and a molding member 230.

The substrate 210 may be a support substrate on which the plurality of semiconductor chips 200a, 200b, and 200c are mounted, and may include a printed circuit board (PCB), a ceramic substrate, a glass substrate, a tape wiring substrate, or the like. The substrate 210 may include a lower pad 212 and an upper pad 211 on lower and upper surfaces thereof, respectively, which may be electrically connected to the outside. Additionally, the substrate 210 may include a wiring circuit 213 electrically connecting the lower pad 212 and the upper pad 211.

The plurality of semiconductor chips 200a, 200b, and 200c may be mounted on the substrate 210 using a wire bonding process or a flip chip bonding process. For example, the plurality of semiconductor chips 200a, 200b, and 200c may be stacked on the substrate 210 in a vertical direction (D3 direction), and may be electrically connected to the upper pad 211 of the substrate 210 by a bonding wire WB. The plurality of semiconductor chips 200a, 200b, and 200c may include a volatile memory chip and/or a non-volatile memory chip.

The molding member 230 may cover or overlap at least a portion of the plurality of semiconductor chips 200a, 200b, and 200c on the substrate 210. The molding member 230 may include the same or similar material as an encapsulant 330, as described above. Connection bumps 215 may be disposed below the substrate 210. The connection bumps 215 may be electrically connected to the plurality of semiconductor chips 200a, 200b, and 200c through the wiring circuit 213. The connection bumps 215 may include, for example, tin (Sn) or an alloy including tin (Sn) (e.g., Sn-Ag-Cu).

The lower chip structures 100A and 100B and the upper chip structures 200A, described above with reference to FIGS. 3A to 3C, are illustrative, and shapes of a lower chip structure 100 and upper chip structure 200, applicable to a semiconductor package according to the present disclosure, are not limited thereto.

FIG. 4A is a plan view of a semiconductor package 300B according to an example embodiment, and FIG. 4B is a cross-sectional view of FIG. 4A, taken along line II-II′.

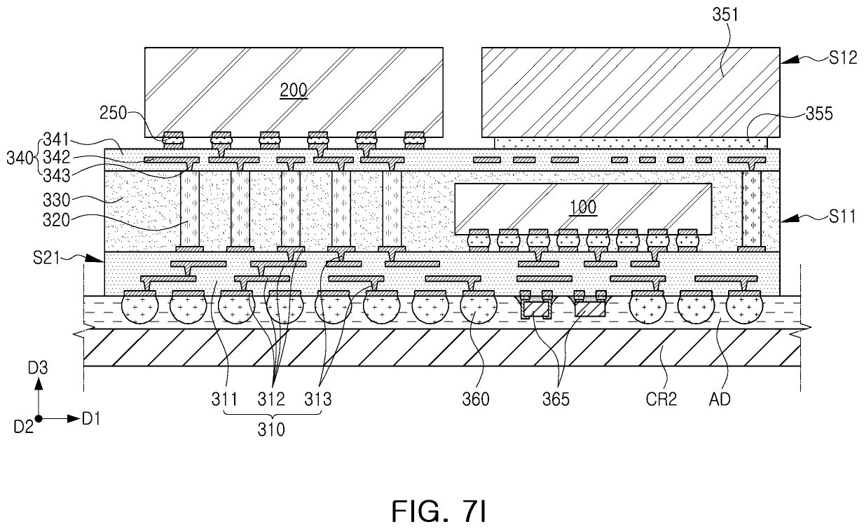

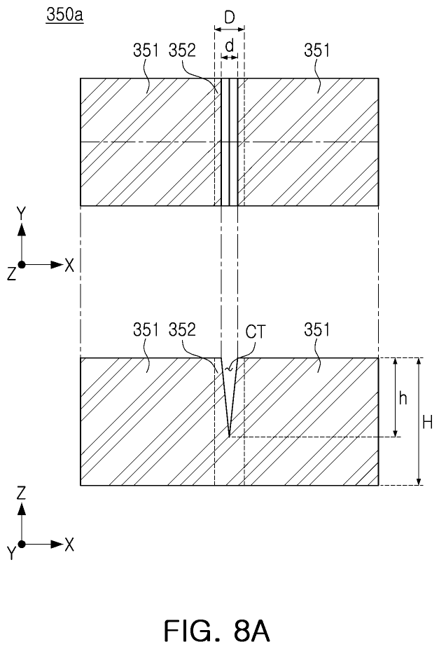

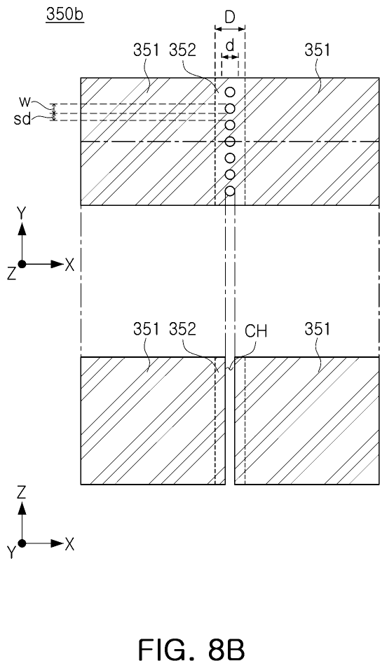

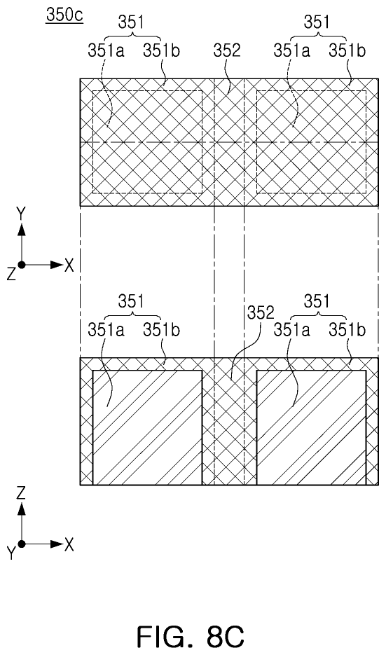

Referring to FIGS. 4A and 4B, a semiconductor package 300B of the example embodiment may have the same or similar features as those described with reference to FIGS. 1A to 3C, except that a heat dissipation member 351 further includes at least one inclined surface S12′ adjacent to an end (or edge) of a unit package structure UP. The heat dissipation member 351 may include the at least one inclined surface S12′ connecting at least one surface, among a first surface S12, a third surface S32, and a fourth surface S42, matching or overlapping the end (or edge) of the unit package structure UP, and an upper surface of the heat dissipation member 351. The inclined surface S12′ may be a remaining portion of a processing portion formed to facilitate a cutting process of a heat dissipation block (see FIG. 8A). A slope of the inclined surface S12′ may be smaller or less than a slope of one of the first, third, and fourth surfaces S12, S32, and S42 of the heat dissipation member 351.

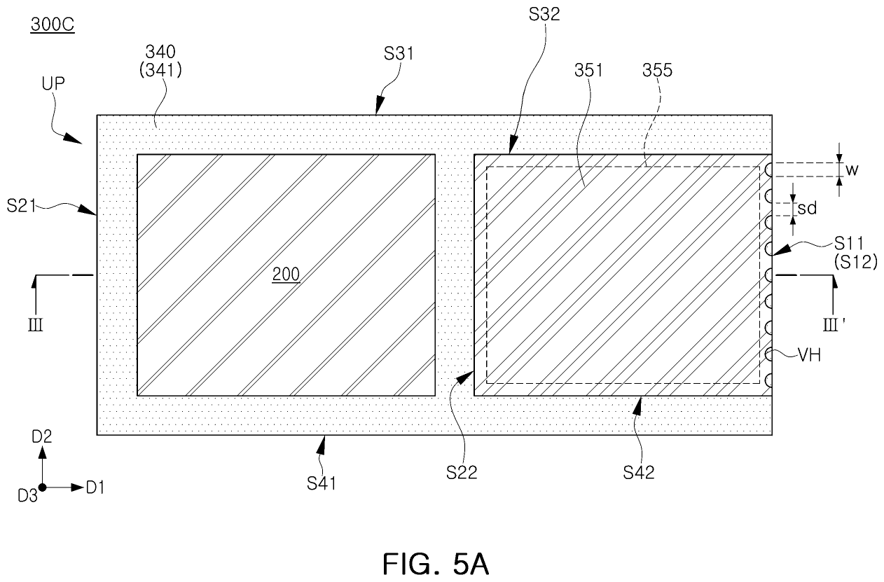

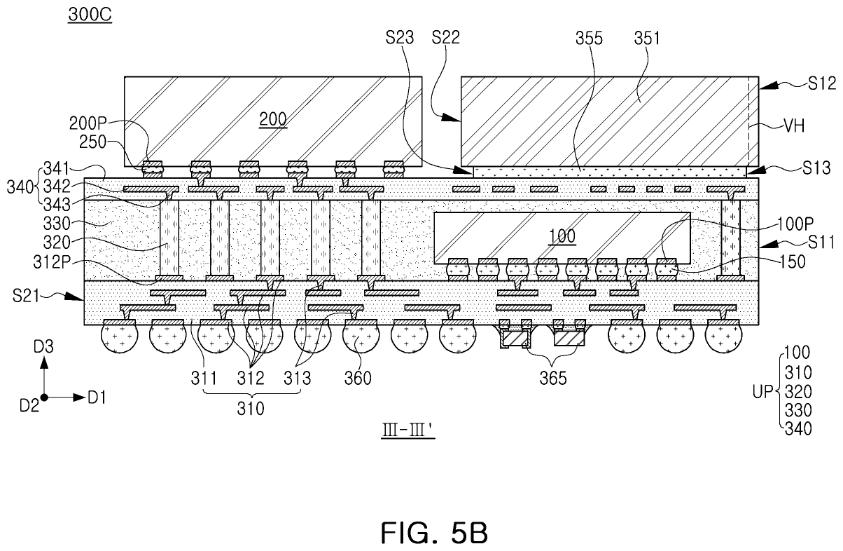

FIG. 5A is a plan view of a semiconductor package 300C according to an example embodiment, and FIG. 5B is a cross-sectional view of FIG. 5A, taken along line III-III′.

Referring to FIGS. 5A and 5B, a semiconductor package 300C of the example embodiment may have the same or similar features as those described with reference to FIGS. 1A to 4B, except that a heat dissipation member 351 further includes a plurality of trenches VH adjacent to an end (or edge) of a unit package structure UP. The heat dissipation member 351 may include the plurality of trenches VH extending in a vertical direction D3 on at least one surface, among a first surface S12, a third surface S32, and a fourth surface S42, matching or overlapping the end (or edge) of the unit package structure UP, and arranged in a horizontal direction (e.g., D2). The plurality of trenches VH may be a remaining portion of a processing portion formed to facilitate a cutting process of a heat dissipation block (see FIG. 8B). A horizontal separation distance sd between the plurality of trenches VH may be equal to or greater than a horizontal width w of each of the plurality of trenches VH.

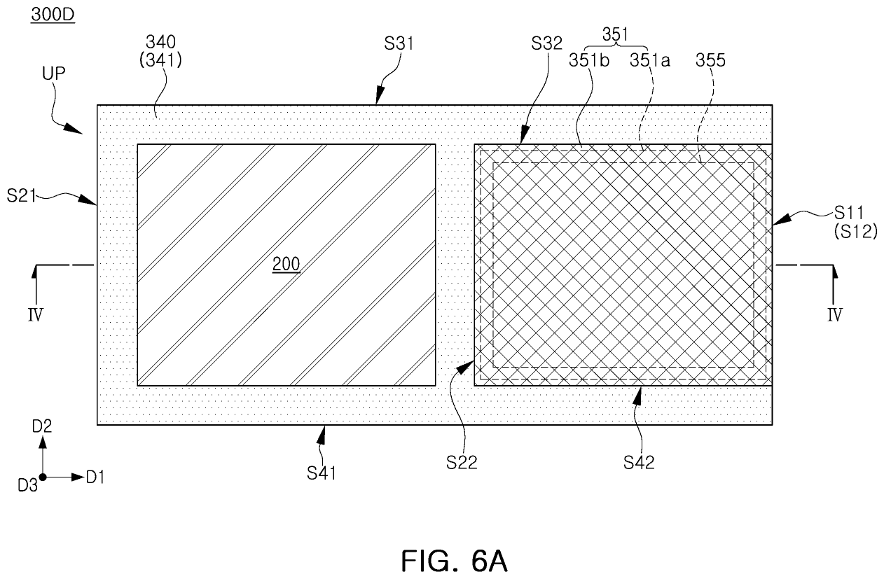

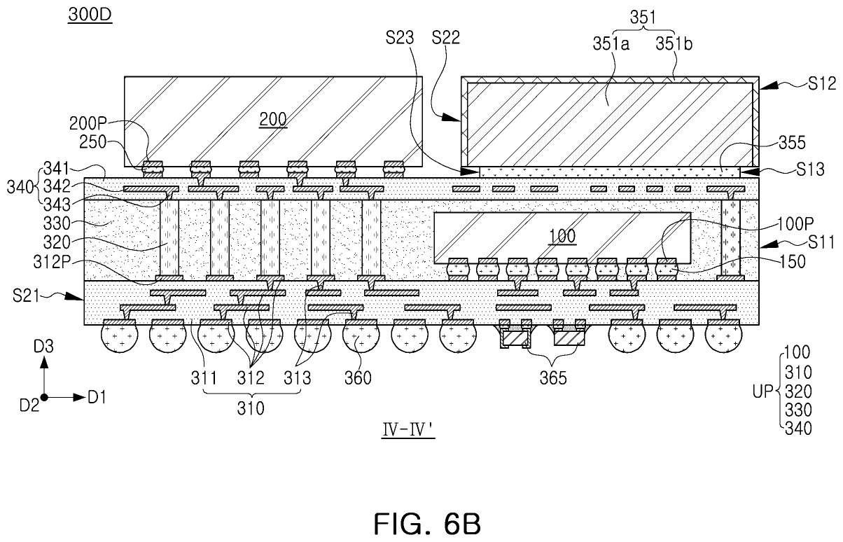

FIG. 6A is a plan view of a semiconductor package 300D according to an example embodiment, and FIG. 6B is a cross-sectional view of FIG. 6A, taken along line IV-IV′.

Referring to FIGS. 6A and 6B, a semiconductor package 300D of the example embodiment may have the same or similar features as those described with reference to FIGS. 1A to 5B, except that a heat dissipation member 351 includes a body portion 351a and a coating portion 351b covering or overlapping a surface of the body portion 351a. The body portion 351a may include a material having excellent thermal conductivity, for example, aluminum (Al), gold (Au), silver (Ag), copper (Cu), iron (Fe), graphite, graphene, or the like. The coating portion 351b may include a polymer material such as an epoxy resin. The coating portion 351b may cover or overlap side and upper surfaces of the body portion 351a. A lower surface of the body portion 351a may be exposed from the coating portion 351b, and may be in contact with the heat transfer material layer 355. The coating portion 351b may entirely surround the side surface of the body portion 351a, and may define a first surface S12, a second surface S22, a third surface S32, and a fourth surface S42 of the heat dissipation member 351 (42) may be defined.

Depending on an embodiment, the coating portion 351b may expose an upper surface of the body portion 351a or cover/overlap only a portion of the side surface of the body portion 351a.

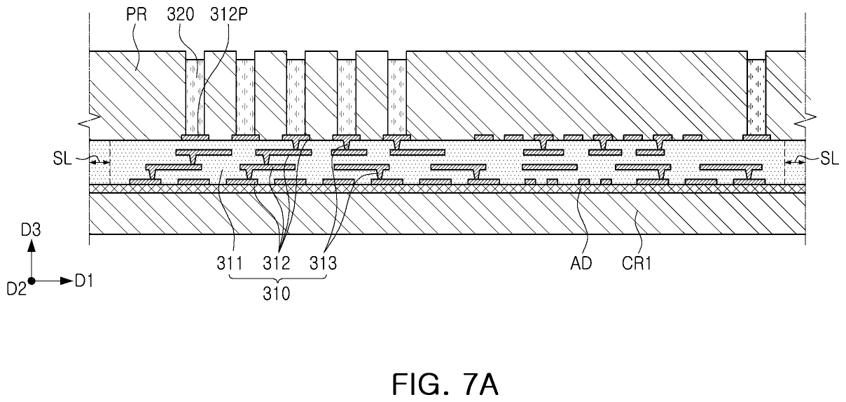

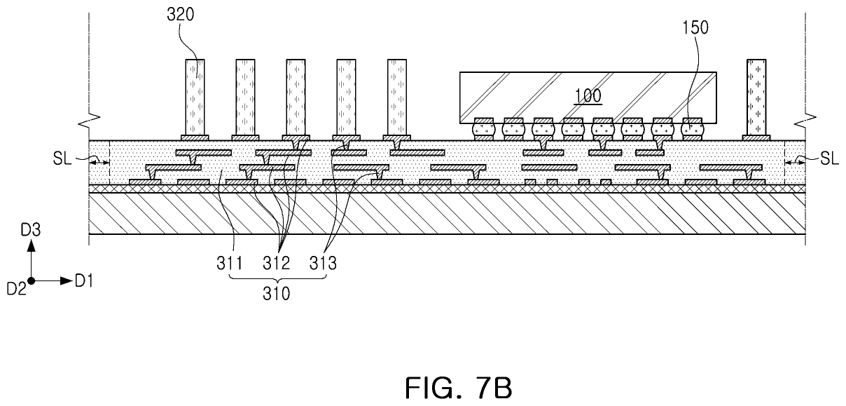

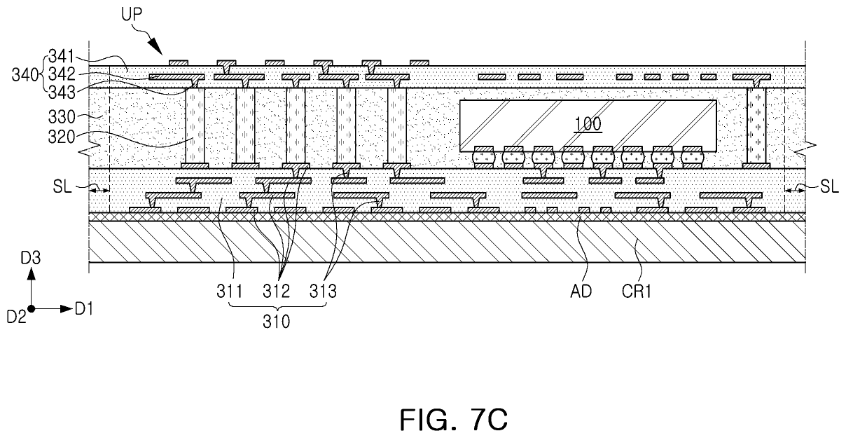

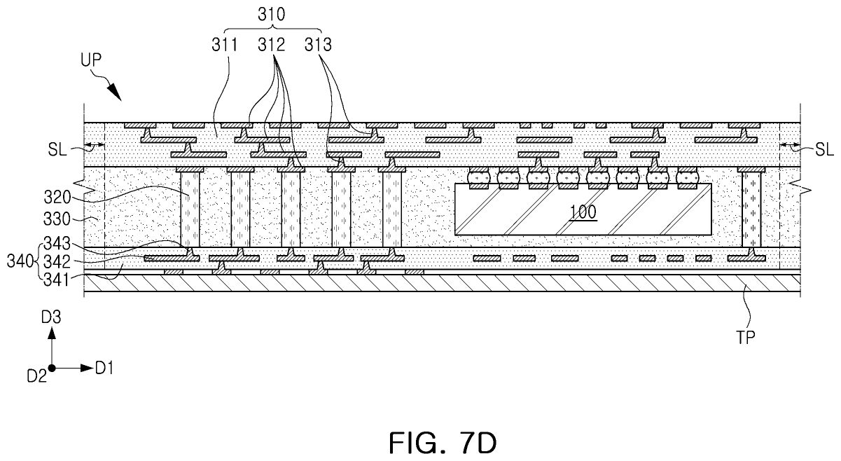

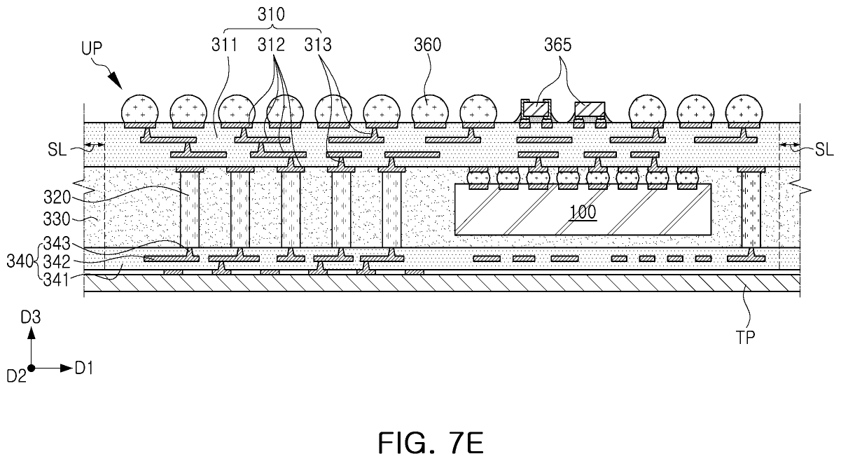

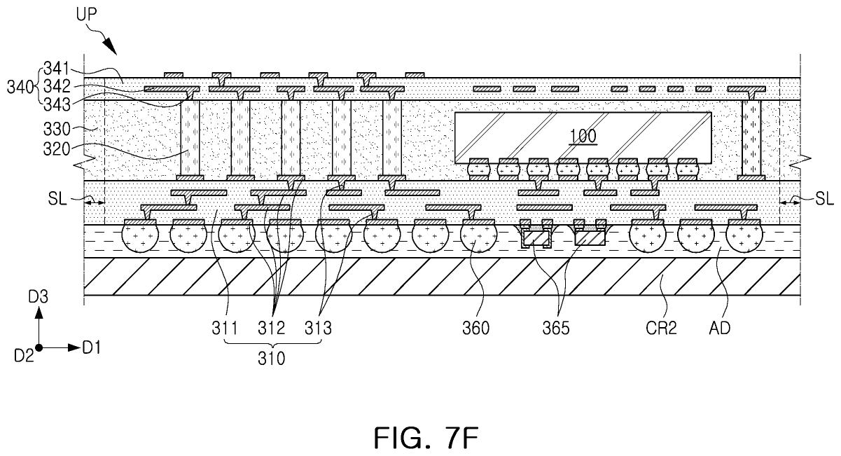

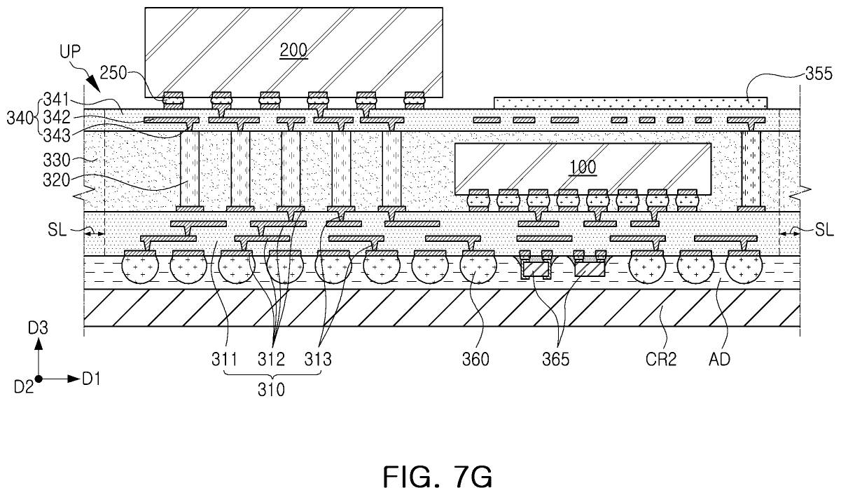

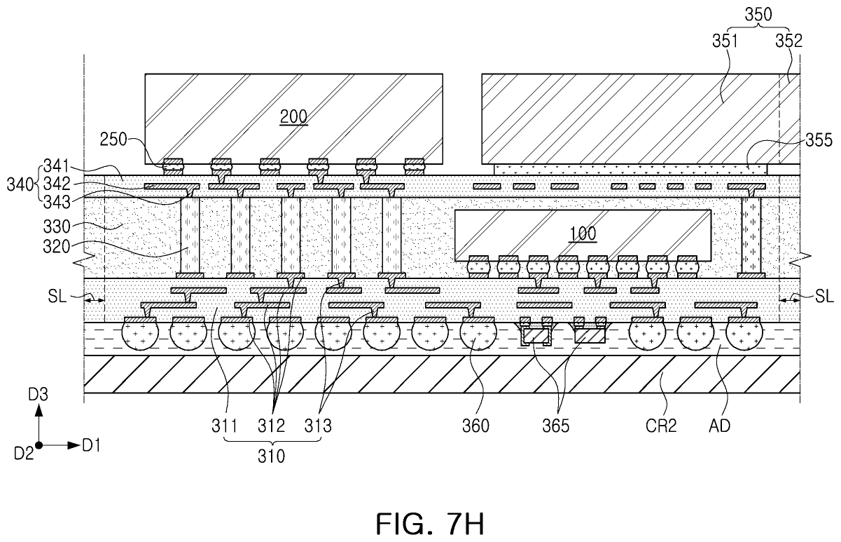

FIGS. 7A to 7I are cross-sectional views illustrating a process of manufacturing a semiconductor package according to an example embodiment.

Referring to FIG. 7A, a lower redistribution structure 310 and a plurality of posts 320 may be formed on a first carrier substrate CR1. The first carrier substrate CR1 may be a temporary support in the form of a wafer or panel. A bonding material layer AD including a curable resin layer may be disposed between the first carrier substrate CR1 and the lower redistribution structure 310. A plurality of lower redistribution structures 310 divided by a scribe lane SL may be formed on a level of the wafer or panel.

The lower redistribution structure 310 may include a lower insulating layer 311, a lower redistribution layer 312, and a lower redistribution via 313. The lower insulating layer 311 may be formed by sequentially applying and curing a photosensitive resin, for example, PID. The lower redistribution layer 312 and the lower redistribution via 313 may be formed by performing an exposure process and a development process to form a via hole passing through or extending into the lower insulating layer 311, and patterning a metal material on the lower insulating layer 311 using a plating process. A redistribution pad 312P may be formed on an upper surface of the lower redistribution structure 310. The plurality of posts 320 may be formed on the redistribution pad 312P of the lower redistribution structure 310 using a photosensitive material layer PR.

Referring to FIG. 7B, a lower chip structure 100 may be mounted on the lower redistribution structure 310. The lower chip structure 100 may be mounted using a flip-chip method. The lower chip structure 100 may be connected to the lower redistribution layer 312 through a lower connection bump 150. Depending on an embodiment, an underfill (not illustrated) may be formed between the lower chip structure 100 and the lower redistribution structure 310. The underfill (not illustrated) may be formed using a capillary underfill (CUF) process, but the present disclosure is not limited thereto.

Referring to FIG. 7C, an encapsulant 330 and an upper redistribution structure 340 may be formed. The lower chip structure 100, the lower redistribution structure 310, the plurality of posts 320, the encapsulant 330, and the upper redistribution structure 340 may form a unit package structure UP divided by scribe lanes SL. The encapsulant 330 may be formed, for example, by applying and curing EMC. The upper redistribution structure 340 may be formed on an upper surface of the encapsulant 330 to which a planarization process has been applied. The planarization process may include a grinding process, a chemical mechanical polishing (CMP) process, or the like. The upper redistribution structure 340 may include an upper insulating layer 341, an upper redistribution layer 342, and an upper redistribution via 343. The upper redistribution structure 340 may be formed by performing substantially the same process as the lower redistribution structure 310.

Referring to FIGS. 7D and 7E, the unit package structure UP may be attached to a temporary tape TP and inverted, and external connection bumps 360 and passive elements 365 may then be formed. The external connection bumps 360 may include a solder ball. The external connection bumps 360 may be attached to the lower redistribution layer 312. The passive elements 365 may be flip-chip mounted on the lower redistribution layer 312.

Referring to FIGS. 7F and 7G, the unit package structures UP may be attached to a second carrier substrate CR2 and inverted, an upper chip structure 200 and a heat transfer material layer 355 may be disposed on the upper redistribution structure 340 of the unit package structures UP. The upper chip structure 200 may be electrically connected to the upper redistribution layer 342 through upper connection bumps 250. The heat transfer material layer 355 may include a thermal interface material (TIM) having a gel type, a pad type, or a film type.

Referring to FIG. 7H, a heat dissipation block 350 may be disposed on the heat transfer material layer 355. The heat dissipation block 350 may include a heat dissipation member 351, and a removal portion 352 integrally connected to the heat dissipation member 351. The heat dissipation block 350 may cover or overlap multiple unit regions to minimize process risks due to warpage (see FIGS. 9A to 9C). The heat dissipation member 351 and the removal portion 352 may be defined depending on whether they remain after the cutting process. For example, the heat dissipation member 351 may be located in a region of the unit package structure UP, and the removal portion 352 may be located in the scribe lane SL. The heat transfer material layer 355 may be disposed only below the heat dissipation member 351 of the heat dissipation block 350. Since the heat transfer material layer 355 may be disposed only in a region overlapping the heat dissipation member 351 downwardly, occurrence of burrs may be reduced and the cutting process described later may be carried out easier.

Referring to FIG. 7I, the heat dissipation member 351 and the unit package structure UP may be separated. At least a portion of the heat dissipation block 350 and at least a portion of the scrap lane SL may be removed by performing a cutting process using a blade, a laser drill, or the like. The heat dissipation member 351 may be a portion of the heat dissipation block 350, for example, a portion remaining after the above-described removal portion 352 has been removed. The unit package structure UP may include side surfaces (e.g., S11, S21) formed through a cutting process. At least one surface (e.g., ‘S12’) of the heat dissipation member 351 connected to the removed portion 352 of the heat dissipation block 350 may be in the same vertical plane (e.g., coplanar) as a side surface (e.g., ‘S11’) of the unit package structure UP. Hereinafter, a heat dissipation block of an example modified embodiment will be described with reference to FIGS. 8A to 8C.

FIGS. 8A to 8C are views illustrating heat dissipation blocks 350a, 350b, and 350c of example modified embodiments.

Referring to FIG. 8A, a heat dissipation block 350a of an example modified embodiment may include a cut portion CT formed in a removal portion 352. The cut portion CT may be formed at a predetermined depth to facilitate a cutting process of the heat dissipation block 350a. A vertical direction (Z-axis) depth h of the cut portion CT may be ⅓ or more of a vertical (Z-axis) thickness H (e.g., about 1 mm) of a heat dissipation member 351, for example, ⅓ to ⅔, but the present disclosure is not limited thereto. The depth h of the cut portion CT may be determined depending on a material of the heat dissipation member 351, conditions of the cutting process, or the like. A horizontal direction (X-axis) width d of the cut portion CT may be smaller than a width D of the removal portion 352, but the present disclosure is not limited thereto. In some modified embodiments, the horizontal (X-axis) width d of the cut portion CT may be greater than the width D of the removed portion 352. In this case, a remaining portion of the cut portion CT may form an inclined surface S12′ of a heat dissipation member 351 illustrated in FIGS. 4A to 4B.

Referring to FIG. 8B, a heat dissipation block 350b of an example modified embodiment may include a plurality of through-holes CH formed in a removal portion 352. The plurality of through-holes CH may entirely pass through a thickness of a heat dissipation member 351 in a vertical direction (Z-axis). Cut portions CT may be arranged at a predetermined distance to facilitate the cutting process of the heat dissipation block 350b. A horizontal (Y-axis) separation distance sd of the plurality of through-holes CH may be smaller than a diameter w of the plurality of through-holes CH. For example, the separation distance sd of the plurality of through-holes CH may be about half of the diameter w (several μm to tens of um) of the plurality of through-holes CH, but the present disclosure is not limited thereto. The horizontal direction (X-axis) diameter w of the plurality of through-holes CH may be smaller than a width D of the removal portion 352, but the present disclosure is not limited thereto. In some modified embodiments, the diameter w of the plurality of through-holes CH may be larger than the width D of the removed portion 352. In this case, a remaining portion of the plurality of through-holes CH may form a plurality of trenches VH of the heat dissipation member 351 illustrated in FIGS. 5A to 5B.

Referring to FIG. 8C, a heat dissipation block 350c of an example modified embodiment may include a body portion 351a and a coating portion 351b integrally connected to the body portion 351a. The coating portion 351b may be formed of a material that may be relatively easy to cut, making it easy to cut the heat dissipation block 350c. The coating portion 351b may include an adhesive polymer material. In some modified embodiments, the coating portion 351b may include a polymer material in which metal particles are dispersed to increase thermal conductivity. The coating portion 351b surrounds a side surface of the body portion 351a, and may integrally connect adjacent body portions 351a. The coating portion 351b may extend to upper and/or lower surfaces of the body portion 351a, but the present disclosure is not limited thereto. As described above, the heat dissipation blocks 350a, 350b, and 350c of example modified embodiments may include a processing portion formed for a cutting process.

FIGS. 9A to 9C are plan views illustrating a portion of a process of manufacturing a semiconductor package according to an example embodiment. FIGS. 9A to 9C illustrate manufacturing processes corresponding to FIGS. 7G to 7I, respectively.

Referring to FIG. 9A, upper chip structures 200 and heat transfer material layers 355 may be disposed on a substrate strip ST. The substrate strip ST may include a plurality of unit package regions UP′ partitioned by a scribe lane SL. Each of the plurality of unit package regions UP′ may be understood to include the same components as the unit package structure UP described with reference to FIG. 7G. Heat transfer material layers 355 may be arranged adjacent to each other in at least one direction.

Referring to FIG. 9B, heat dissipation blocks 350 may be disposed on the heat transfer material layers 355. The heat dissipation blocks 350 may have an area covering or overlapping at least two heat transfer material layers 355. The heat dissipation blocks 350 may include a heat dissipation member 351 located in the plurality of unit package regions UP' and a removal portion 352 located in the scribe lane SL. According to an example embodiment, an occupied area of the heat dissipation blocks 350 in a substrate strip ST may increase to reduce warpage of the substrate strip ST and improve process reliability and yield.

Referring to FIG. 9C, the heat dissipation member 351 and the unit package structure UP may be separated along the scribe lane SL. By the cutting process, the removal portion 352 of the heat dissipation block 350 and the scribe lane SL of the substrate strip ST may be removed. At least one surface of the heat dissipation member 351 connected to the removed portion 352 of the heat dissipation block 350 may form the same plane (e.g., coplanar) as the side surface of the unit package structure UP.

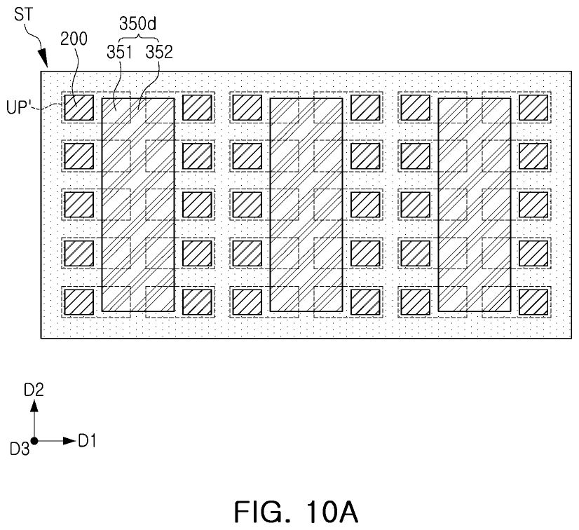

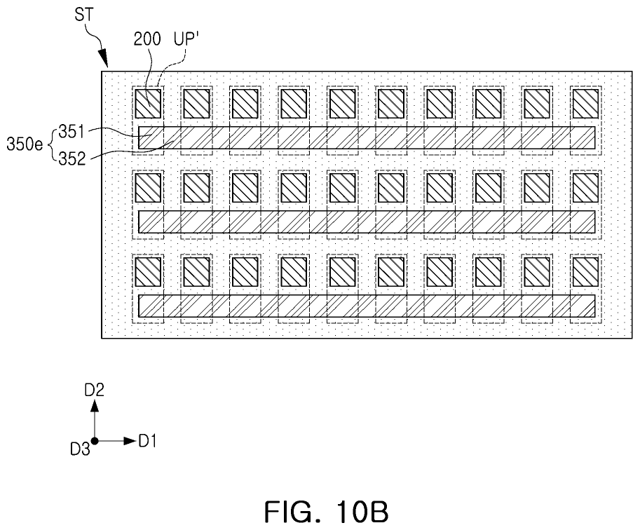

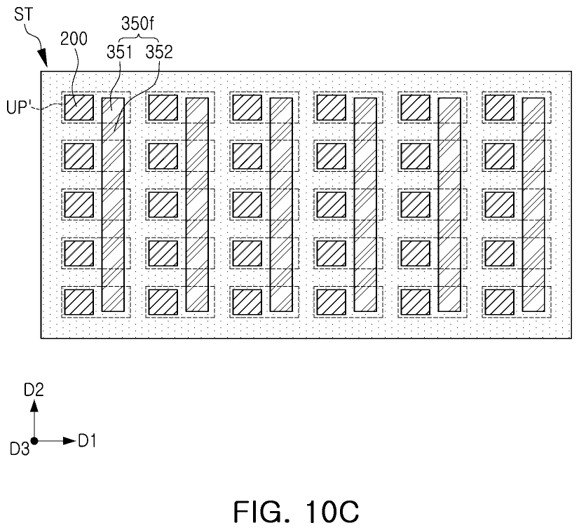

FIGS. 10A to 10C are plan views illustrating heat dissipation blocks 350d, 350e, and 350f of example modified embodiments.

Referring to FIG. 10A, a heat dissipation block 350d of an example modified embodiment may cover or overlap two or more unit package regions UP′ in a first horizontal direction D1 and a second horizontal direction D2, respectively. For example, upper chip structures 200 in odd-numbered rows may be arranged correctly based on an alignment key, and upper chip structures 200 in even-numbered rows may be reversely arranged (rotated 180°) based on the alignment key. The heat dissipation block 350d may have a width that may cover or overlap both odd-numbered rows of unit package regions UP′ and even-numbered rows of unit package regions UP′ in the first horizontal direction D1. Additionally, the heat dissipation block 350d may have a width that may cover or overlap two or more rows of unit package regions UP′ in the second horizontal direction D2.

Referring to FIG. 10B, a heat dissipation block 350e of an example modified embodiment may extend in a long axis direction of a substrate strip ST. The heat dissipation block 350e may cover or overlap two or more unit package regions UP' in the long axis direction of the substrate strip ST. For example, in the substrate strip ST, the unit package regions UP′ may be arranged such that heat transfer material layers are adjacent to each other in the first horizontal direction D1. An upper chip structure 200 may be aligned in a unit package region UP′ corresponding thereto. The heat dissipation block 350e may have a width that may cover or overlap all of the unit package regions UP′ in the first horizontal direction D1.

Referring to FIG. 10C, a heat dissipation block 350f of an example modified embodiment may extend in a minor axis direction of a substrate strip ST. The heat dissipation block 350f may cover or overlap two or more unit package regions UP′ in the minor axis direction of the substrate strip ST. For example, in the substrate strip ST, the unit package regions UP′ may be arranged such that heat transfer material layers are adjacent to each other in the second horizontal direction D2. An upper chip structure 200 may be aligned in a unit package region UP′ corresponding thereto. The heat dissipation block 350f may have a width that may cover or overlap all of the unit package regions UP′ in the second horizontal direction D2.

According to embodiments, a heat dissipation block covering a plurality of unit package regions in a substrate strip may be introduced, to reduce process risks and provide a semiconductor package having improved reliability.

Various advantages and effects of the present disclosure are not limited to the above-described contents, and can be more easily understood through description of specific embodiments.

While example embodiments have been illustrated and described above, it will be apparent to those skilled in the art that modifications and variations could be made without departing from the scope of the present disclosure as defined by the appended claims.

What is claimed is:

1. A semiconductor package comprising:
a lower redistribution structure that comprises a lower redistribution layer;
a lower chip structure that is on an upper surface of the lower redistribution structure and is electrically connected to the lower redistribution layer;
an encapsulant on the lower chip structure;
an upper redistribution structure that is on the encapsulant and comprises an upper redistribution layer;
a plurality of posts that extend into the encapsulant and electrically connect the lower redistribution layer and the upper redistribution layer;
an upper chip structure that is on the upper redistribution structure and is electrically connected to the upper redistribution layer;
a heat dissipation member that is on a first side of the upper chip structure and overlaps at least a portion of the lower chip structure in a first direction that is perpendicular to a lower surface of the lower redistribution structure that is opposite to the upper surface of the lower redistribution structure; and
external connection bumps that are on the lower surface of the lower redistribution structure and are electrically connected to the lower redistribution layer,
wherein, in plan view, the heat dissipation member comprises a first surface, a second surface opposite to the first surface a third surface and a fourth surface opposite to the first surface,
the second surface of the heat dissipation member faces the first side of the upper chip structure, and
at least one of the first surface, the third surface, and the fourth surface of the heat dissipation member overlaps an edge of the lower redistribution structure, an edge of the encapsulant, and an edge of the upper redistribution structure in the first direction.

2. The semiconductor package of claim 1, wherein at least one of the first surface, the third surface, and the fourth surface of the heat dissipation member is coplanar with the edge of the lower redistribution structure, the edge of the encapsulant, and the edge of the upper redistribution structure.

3. The semiconductor package of claim 1, wherein:
two of the first surface, the third surface, or the fourth surface of the heat dissipation member overlaps the edge of the lower redistribution structure, the edge of the encapsulant, and the edge of the upper redistribution structure in the first direction, and
a remaining one of the first surface, the third surface, or the fourth surface of the heat dissipation member is spaced apart from the edge of the lower redistribution structure, the edge of the encapsulant, and the edge of the upper redistribution structure in a second direction that is parallel to the lower surface of the lower redistribution structure.

4. The semiconductor package of claim 1, wherein each of the first surface, the third surface, and the fourth surface of the heat dissipation member overlap the edge of the lower redistribution structure, the edge of the encapsulant, and the edge of the upper redistribution structure in the first direction.

5. The semiconductor package of claim 1, further comprising a heat transfer material layer between the heat dissipation member and the upper redistribution structure,
wherein the heat transfer material layer comprises a first edge, a second edge, a third edge, and a fourth edge spaced apart from the first surface, the second surface, the third surface, and the fourth surface, respectively, of the heat dissipation member in a second direction that is parallel to the lower surface of the lower redistribution structure.

6. The semiconductor package of claim 5, wherein, in the plan view, the heat transfer material layer is on a planar area of the heat dissipation member.

7. The semiconductor package of claim 1, wherein a first number of the plurality of posts that overlap the upper chip structure in the first direction is greater than a second number of the plurality of posts that overlap the heat dissipation member in the first direction.

8. The semiconductor package of claim 1, wherein:
the heat dissipation member further comprises at least one inclined surface connecting an upper surface of the heat dissipation member and one of the first surface, the third surface, or the fourth surface and,
wherein a slope of the at least one inclined surface is less than a slope of the one of the first surface, the third surface, or the fourth surface.

9. The semiconductor package of claim 8, wherein a height of the at least one inclined surface in the first direction is greater than or equal to ⅓ of a thickness of the heat dissipation member in the first direction.

10. The semiconductor package of claim 1, wherein:
the heat dissipation member further comprises a plurality of trenches that extend in the first direction on at least one of the first surface, the third surface, and the fourth surface, and
the plurality of trenches are spaced apart in a second direction that is parallel to the upper surface of the lower redistribution structure.

11. The semiconductor package of claim 10, wherein a separation distance between the plurality of trenches in the second direction is greater than or equal to a width of the plurality of trenches in the second direction.

12. The semiconductor package of claim 1, wherein:
the heat dissipation member comprises a body portion and a coating portion on the body portion,
the body portion comprises metal, and
the coating portion comprises a polymer material.

13. The semiconductor package of claim 12, wherein the coating portion is on side surfaces and upper surfaces of the body portion.

14. The semiconductor package of claim 1, wherein:
the lower chip structure comprises at least one logic chip, and
the upper chip structure comprises at least one memory chip.

15. A semiconductor package comprising:
a unit package structure that comprises a lower chip structure, wherein the unit package structure comprises a first side surface and a second side surface that are opposite to each other, and wherein the unit package structure comprises a third side surface and a fourth side surface that are opposite to each other;
a heat dissipation member that is on the unit package structure and adjacent to the first side surface;
an upper chip structure that is on the unit package structure and adjacent to the second side surface;
a heat transfer material layer between the heat dissipation member and the unit package structure; and
external connection bumps that are on the unit package structure and are electrically connected to the lower chip structure and the upper chip structure,
wherein the heat dissipation member comprises a first surface adjacent to the first side surface of the unit package structure, a second surface adjacent to the upper chip structure, a third surface adjacent to the third side surface, and a fourth surface adjacent to the fourth side surface,
wherein the heat transfer material layer comprises a first edge adjacent to the first surface, a second edge adjacent to the second surface, a third edge adjacent to the third surface, and a fourth edge adjacent to the fourth surface, wherein the first surface of the heat dissipation member is aligned with the first side surface of the unit package structure in a first direction that is perpendicular to a lower surface of the unit package structure, the third surface of the heat dissipation member is aligned with the third side surface of the unit package structure in the first direction, and/or the fourth surface of the heat dissipation member is aligned with the fourth side surface of the unit package structure in the first direction, and
wherein the first edge of the heat transfer material layer is spaced apart from the first side surface of the unit package structure in a second direction that is parallel to the lower surface of the unit package structure, the third edge of the heat transfer material layer is spaced apart from the third side surface of the unit package structure in the second direction, and/or the fourth edge of the heat transfer material layer is spaced apart from the fourth side surface of the unit package structure in the second direction.

16. The semiconductor package of claim 15 wherein the unit package structure comprises:
a lower redistribution structure, wherein the lower chip structure is on the lower redistribution structure,
an upper redistribution structure on the lower chip structure,
an encapsulant between the lower redistribution structure and the upper redistribution structure, and
a plurality of posts that extend into the encapsulant and electrically connect the lower redistribution structure and the upper redistribution structure.

17. The semiconductor package of claim 15, wherein the heat dissipation member further comprises an inclined surface extending from:
the first surface, the third surface, the fourth surface,
a plurality of trenches extending in the first direction along the first surface, the third surface, or the fourth surface, or
a coating portion on an entirety of the first surface, the third surface, or the fourth surface.

18. A semiconductor package comprising:
a unit package structure that comprises a lower redistribution structure, a lower chip structure on the lower redistribution structure, an upper redistribution structure on the lower chip structure, and a plurality of posts electrically connecting the lower redistribution structure and the upper redistribution structure; and
a heat dissipation member and an upper chip structure that are on the unit package structure,
wherein, in plan view, the heat dissipation member extends to an edge of the unit package structure in at least one of a first direction, a third direction perpendicular to the first direction, and a fourth direction opposite to the third direction, and
wherein the heat dissipation member is adjacent to the upper chip structure in a second direction that is opposite to the first direction.

19. The semiconductor package of claim 18, wherein:
the heat dissipation member comprises a first surface that faces the first direction, a second surface that faces the second direction, a third surface that faces the third direction, and a fourth surface that faces the fourth direction,
wherein at least one of the first surface, the third surface, and the fourth surface is aligned with the edge of the unit package structure.

20. The semiconductor package of claim 18, wherein the heat dissipation member further comprises:
an inclined surface adjacent to the edge of the unit package structure, or
a plurality of trenches along the edge of the unit package structure.
